(19) United States
(12) Patent Application Publication
(10) Pub. No.: US 2015/0020734 A1
(43) Pub. Date: Jan. 22, 2015

(54) STRUCTURE FOR IMPROVED GAS ACTIVATION FOR CROSS-FLOW TYPE THERMAL CVD CHAMBER

(71) Applicant: Applied Materials, Inc., Santa Clara, CA (US)

(72) Inventors: Zhiyuan YE, San Jose, CA (US); Mehmet Tugrul SAMIR, Mountain View, CA (US)

(21) Appl. No.: 14/332,019

(22) Filed: Jul. 15, 2014

Related U.S. Application Data
(60) Provisional application No. 61/874,572, filed on Sep. 6, 2013.
(60) Provisional application No. 61/847,275, filed on Jul. 17, 2013.

(51) Int. Cl. C23C 16/455

(52) U.S. Cl. CPC C23C 16/4558; C23C 16/45582; C23C 16/45591
USPC 118/715

(57) ABSTRACT

Embodiments described herein generally relate to a processing apparatus having a preheat ring for preheating the process gas. The preheat ring is disposed on a ring support. The preheat ring may have a segment adjacent a process gas inlet. The segment includes a top surface, and the top surface includes features to increase the surface area. In one embodiment, the feature is a plurality of protrusions. In another embodiment, the feature is a plurality of linear fins. In another embodiment, the preheat ring includes a first sub ring and a second sub ring disposed on the first sub ring, wherein the features are located on one segment of the second sub ring.

### CROSS-REFERENCE TO RELATED APPLICATIONS

This application claims benefit of U.S. Provisional Patent Application Ser. Nos. 61/847,275 (APPM 20676L), filed Jul. 17, 2013, and 61/874,572 (APPM 20676L02), filed Sep. 6, 2013, which are herein incorporated by reference.

### BACKGROUND

1. Field

Embodiments described herein generally relate to thermal chemical vapor deposition (CVD) chambers.

2. Description of the Related Art

Continuous reduction in size of semiconductor devices is dependent upon more precise control of, for instance, the flow and temperature of process gases delivered to a semiconductor process chamber. Typically, in a cross-flow process chamber, a process gas may be delivered to the chamber and directed across the surface of a substrate to be processed. The process gas may be heated by a preheat ring, which surrounds the substrate support.

As the process temperature reduces, process gas activation becomes a challenge in thermal CVD chambers. Insufficient process gas activation causes low precursor utilization and poor thickness profile. In a large process chamber for processing substrates having large diameter, such as 450 mm, process gas needs to flow across the substrate fast enough to overcome depletion effect. A larger preheat zone may help achieve sufficient process gas activation, however, chamber foot print limits the size of the preheat zone.

Therefore, there is a need for a processing apparatus having improved process gas preheating.

### SUMMARY

Embodiments described herein generally relate to a processing apparatus having a preheat ring for preheating the process gas. The preheat ring is disposed on a ring support. The preheat ring may have a segment adjacent a process gas inlet. The segment includes a top surface, and the top surface includes features to increase the surface area. In one embodiment, the feature is a plurality of protrusions. In another embodiment, the feature is a plurality of linear fins. In another embodiment, the preheat ring includes a first sub ring and a second sub ring disposed on the first sub ring, wherein the features are located on one segment of the second sub ring.

In one embodiment, an apparatus for processing a substrate is disclosed. The apparatus includes a chamber body having a side wall and a bottom wall defining an interior processing region, a substrate support disposed in the interior processing region of the chamber body, a ring support, and a preheat ring disposed on the ring support. The preheat ring includes at least three linear and parallel fins disposed on one segment of the preheat ring.

In another embodiment, an apparatus for processing a substrate is disclosed. The apparatus includes a chamber body having a side wall and a bottom wall defining an interior processing region, a substrate support disposed in the interior processing region of the chamber body, a ring support, a first preheat ring disposed on the ring support, and a second preheat ring disposed on the first preheat ring.

In another embodiment, an apparatus for processing a substrate is disclosed. The apparatus includes a chamber body having a side wall and a bottom wall defining an interior processing region, a substrate support disposed in the interior processing region of the chamber body, a ring support, and a preheat ring disposed on the ring support. The preheat ring includes a segment disposed adjacent a process gas inlet, and the segment includes a top surface and a plurality of protrusions are disposed on the top surface.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a cross sectional view of a processing chamber according to one embodiment.

FIGS. 2A-2C are top views of a preheat ring according to one embodiment described herein.

FIG. 3 is a cross sectional view of a preheat ring according to one embodiment described herein.

FIG. 4 is a cross sectional view of a preheat ring according to one embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a processing apparatus having a preheat ring for preheating the process gas. The preheat ring is disposed on a ring support. The preheat ring may have a segment adjacent a process gas inlet. The segment includes a top surface, and the top surface includes features to increase the surface area. In one embodiment, the feature is a plurality of protrusions. In another embodiment, the feature is a plurality of linear fins. In another embodiment, the preheat ring includes a first sub ring and a second sub ring disposed on the first sub ring, wherein the features are located on one segment of the second sub ring.

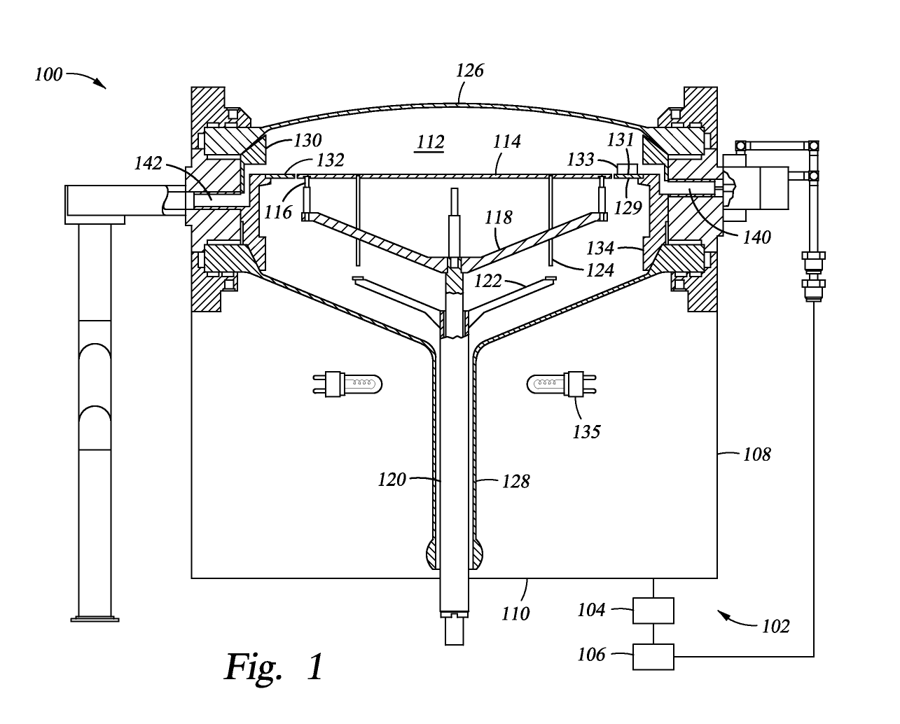

FIG. 1 is a cross sectional view of a processing chamber 100 according to an embodiment described herein. The processing chamber 100 comprises a chamber body 102, support systems 104, and a controller 106. The chamber body 102 having a side wall 108 and a bottom wall 110 defining an interior processing region 112. A substrate support 114 used for supporting a substrate is disposed in the interior processing region 112. In one embodiment, the substrate support 114 is a susceptor. The substrate support 114 is supported by support posts 116, which are connected with supporting arms 118 that extend from a shaft 120. During operation, the substrate disposed on the substrate support 114 may be raised by substrate lift arms 122 through lift pins 124.

An upper dome 126 is disposed over the substrate support 114 and a lower dome 128 is disposed below the substrate support 114. Deposition processes generally occur on the upper surface of the substrate disposed on the substrate support 114 within the interior processing region 112.

An upper liner 130 is disposed below the upper dome 126 and is adapted to prevent undesired deposition onto chamber components. The upper liner 130 is positioned adjacent to a preheat ring 132. The preheat ring 132 is removably disposed on a ring support 134 that is coupled to the side wall 108. In one embodiment, the ring support 134 is a lower liner and is made of quartz. The preheat ring 132 circumscribes the substrate support 114 while the substrate support 114 is in a processing position. The preheat ring 132 is formed from silicon carbide, but it is contemplated that the preheat ring 132 may be formed from other materials such quartz or graphite coated with silicon carbide. The preheat ring 132 includes a segment 129 that is disposed adjacent a process gas inlet 140. The segment 129 has a top surface 131 and process gases flow across the top surface 131 from the process gas inlet 140 during operation. The top surface 131 includes features that increase the surface area of the top surface 131. With an increased surface area, the preheating of the process gases is improved, leading to improved process gas activation. The features may include a plurality of protrusions. In one embodiment, the feature is a plurality of linear fins 133 disposed on the top surface 131 of the segment 129 adjacent the process gas inlet 140. In another embodiment, the preheat ring 132 includes two preheat sub rings. The preheat ring 132 is described in detail below.

The processing chamber 100 includes a plurality of heat sources, such as lamps 135, which are adapted to provide thermal energy to components positioned within the processing chamber 100. For example, the lamps 135 may be adapted to provide thermal energy to the substrate and the preheat ring 132. The lower dome 128 may be formed from an optically transparent material, such as quartz, to facilitate the passage of thermal radiation therethrough. The temperature of the preheat ring 132 during operation is about 100 degrees Celsius to about 200 degrees Celsius less than the temperature of the substrate support 114. In one embodiment, the substrate support 114 is heated to 1000 degrees Celsius and the preheat ring 132 is heated to 800 degrees Celsius. Typically the preheat ring 132 has a temperature between about 300 degrees Celsius and about 800 degrees Celsius during operation. The heated preheat ring 132 activates the process gases as the process gases flow into the processing chamber 100 through the process gas inlet 140. The process gases exit the processing chamber 100 through the process gas outlet 142. In such a manner, the process gases may flow parallel to the upper surface of the substrate. Thermal decomposition of the process gases onto the substrate to form one or more layers on the substrate is facilitated by the lamps 135.

The support system 104 includes components used to execute and monitor pre-determined processes, such as the growth of films in the processing chamber 100. The support system 104 includes one or more of gas panels, gas distribution conduits, vacuum and exhaust sub-systems, power supplies, and process control instruments. A controller 106 is coupled to the support system 104 and is adapted to control the processing chamber 100 and support system 104. The controller 106 includes a central processing unit (CPU), a memory, and support circuits. Instructions resident in controller 106 may be executed to control the operation of the processing chamber 100. Processing chamber 100 is adapted to perform one or more film formation or deposition processes therein. For example, a silicon carbide epitaxial growth process may be performed within processing chamber 100. It is contemplated that other processes may be performed within processing chamber 100.

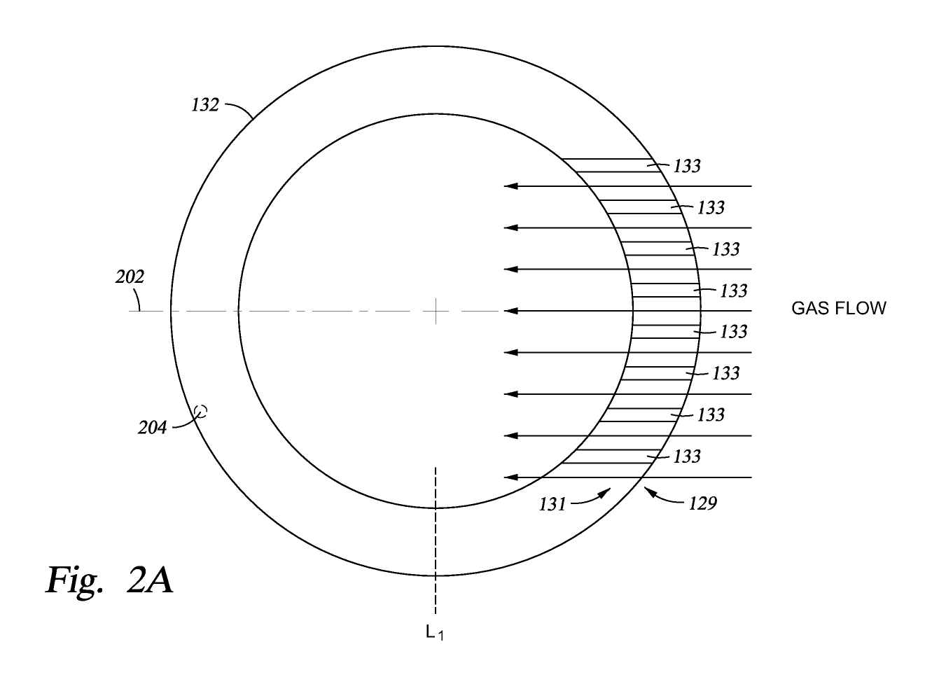

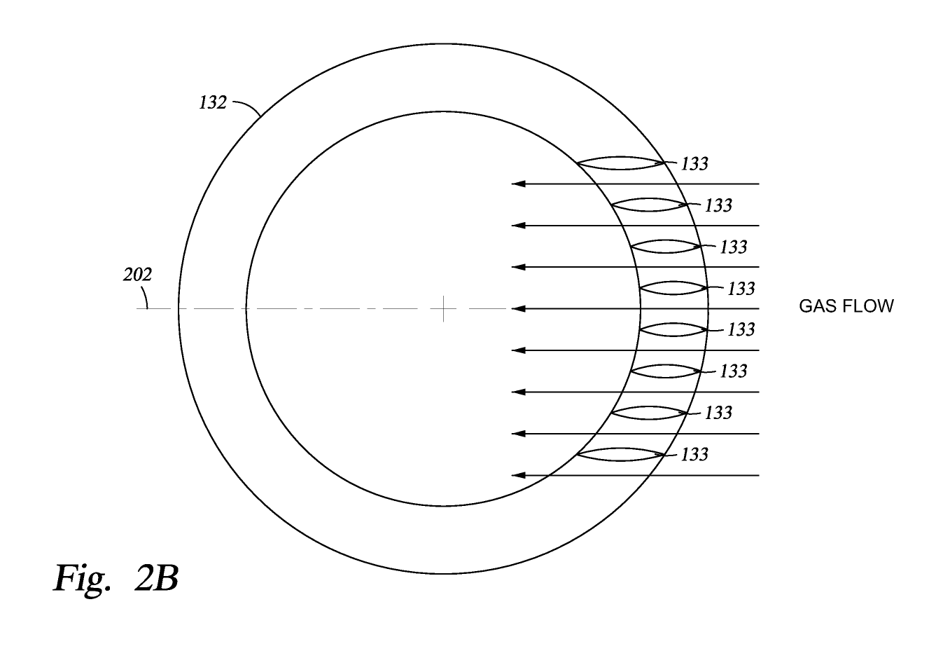

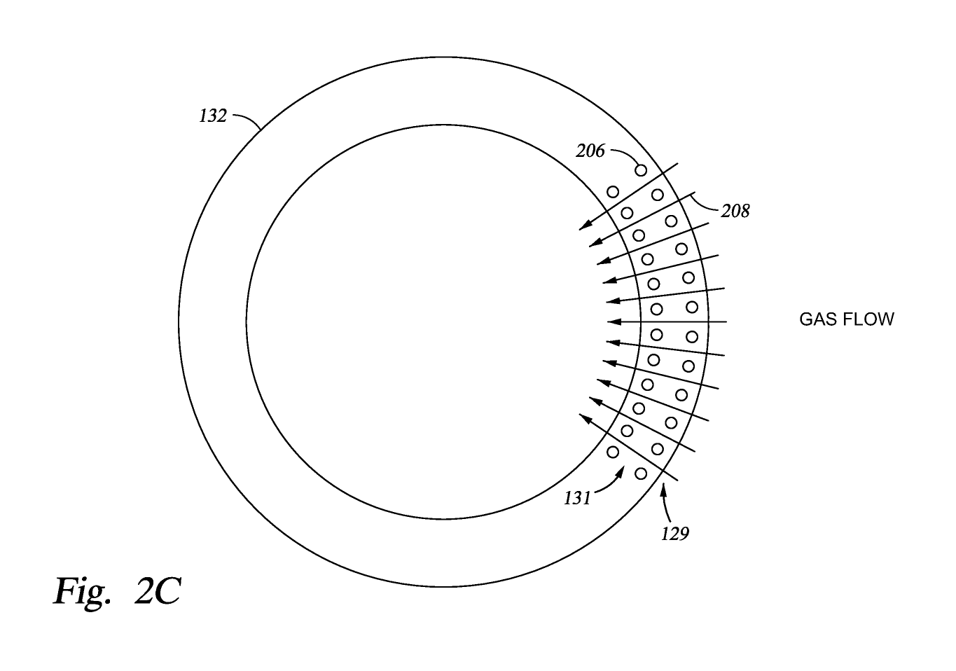

FIGS. 2A-2C are top views of the preheat ring 132 according to one embodiment described herein. As shown in FIG. 2A, to improve preheating of the process gases, a plurality of linear fins 133 is fixed to the top surface 131 of the segment 129 of the preheat ring 132. The linear fins 133 may occupy a portion of the preheat ring 132 based on the size of the process gas inlet 140. In other words, the segment 129 may vary based on the size of the process gas inlet 140. In one embodiment, the segment 129 is about one third of the preheat ring 132, which means that the linear fins 133 occupy about one third of the preheat ring 132, as shown in FIG. 2. The number of and the spacing of the linear fins 133 may be depending on the configuration of a gas injector disposed between the gas inlet 140 and the preheat ring 132. In one embodiment, there are at least three fins, such as eight fins, as shown in FIG. 2. In one embodiment, the linear fins 133 may be parallel to each other, and the linear fins 133 may be parallel to an imaginary center line 202 bisecting the preheat ring 132. The linear fins 133 are substantially aligned along the flow path of the process gases. During operation, process gases flow through the channels between the linear fins 133, as shown in FIG. 2A. The linear fins 133 are heated, thus creating more contact area for better preheating of the process gases. An optional cover (not shown) may be placed on the fins 133, so process gases are flowed through a plurality of pipes formed by the fins 133 and the cover. The linear fins 133 may be streamlined for better gas flow dynamic.

The substrate support 114 may be rotating during operation, which may cause the preheat ring 132 to rotate inadvertently. To reduce the inadvertent rotation of the preheat ring 132, one or more positioning devices 204 may be disposed on a bottom surface of the preheat ring 132. Since FIG. 2A illustrates the top surface 131 of the preheat ring 132, the one or more positioning devices 204 is shown using dotted lines. The one or more positioning devices 204 may be one or more protrusions that are configured to be placed in corresponding recesses disposed on the ring support 134. In addition, since the preheat ring 132 is asymmetric, there may be thermal expansion issues. By making a cut at “L1” as shown in FIG. 2A, thermal expansion issues may be alleviated.

FIG. 2B is a top view of the preheat ring 132 having a plurality of linear fins 133 that are streamlined. Each of the fins 133 has a first end and a second end that is opposite the first end, and the first and second ends are tapered to a point. The pointy ends of the fins 133 should minimize disturbance on the gas flow. The middle section of a fin 133 is wide enough to have the mechanical strength, which leads to a narrow channel cross-section in the middle. The narrow cross-section compresses the gas flow which enhances the heat contact and transfer.

FIG. 2C is a top view of the preheat ring 132 according to one embodiment. As shown in FIG. 2C, a plurality of protrusions 206 are disposed on the top surface 131 of the segment 129. Process gases may flow through the gas paths 208 formed by the protrusions 206. The protrusions 206 may be disposed in any suitable arrangement. In one embodiment, the protrusions 206 may be disposed in an arrangement such that the gas paths 208 are radial, as shown in FIG. 2C. In another embodiment, the protrusions 206 may be disposed in an arrangement such that the gas paths 208 are parallel to each other. The protrusions 206 may be in the form of bumps, as shown in FIG. 2C, or in the form of ripples, ridges, or any suitable nonlinear design. The ripples and ridges may be aligned radially, substantially parallel to the gas flow, or substantially perpendicular to the gas flow.

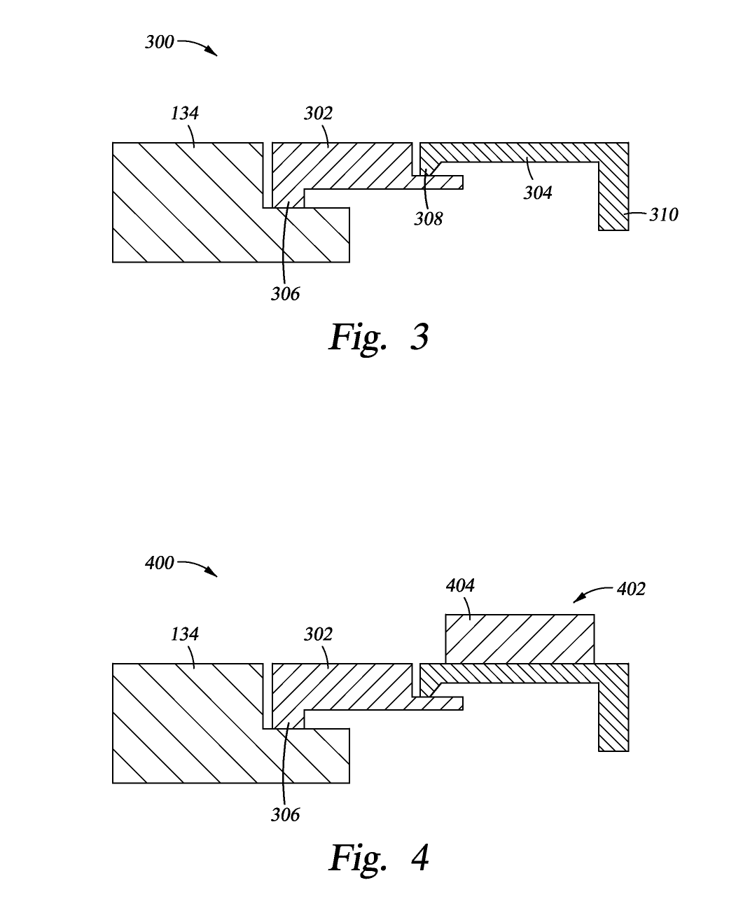

FIG. 3 is a cross sectional view of a preheat ring 300 according to one embodiment described herein. The preheat ring 300 includes a first sub ring 302 disposed on the ring support 134 and a second sub ring 304 disposed on the first sub ring 302. The ring support 134 is coupled to the side wall 108 which may be water cooled. Thus, the cold ring support 134 may reduce the temperature of the preheat ring 300. To reduce the effect of cooling by the lower liner 134, the dual-ring preheat ring 300 is utilized. The first sub ring 302 has a narrow vertical stand 306 contacting the ring support 134 and the second sub ring 304 has a point or slanted stand 308 contacting the first sub ring 302. The small contact areas reduces the heat transferred from the preheat ring 300 to the cold ring support 134, thus the temperature of the second sub ring 304 is increased. The second sub ring 304 has a second vertical stand 310 disposed at an end opposite the point or slanted stand 308. The vertical stand 310 provides a heat shield to limit direct radiation from the substrate support 114 to the ring support 134 and other components. The vertical stand 310 also improves structural strength.

FIG. 4 is a cross sectional view of a preheat ring 400 according to one embodiment described herein. The preheat ring 400 is also a dual-ring preheat ring having the first sub ring 302 and a second sub ring 402. The second sub ring 402 is similar to the second sub ring 304 as shown in FIG. 3, except the second sub ring 402 has a plurality of linear fins 404 fixed to the second sub ring 402 at a segment adjacent the process gas inlet 140. The linear fins 404 may be the same fins as the linear fins 133. Again the linear fins 404 may occupy a portion of the second sub ring 402 based on the size of the process gas inlet 140. In one embodiment, the linear fins 404 occupy a segment that is one third of the second sub ring 402. The number of and the spacing of the linear fins 404 may be depending on the configuration of a gas injector disposed between the gas inlet 140 and the preheat ring 400. In one embodiment, there are at least three fins, such as eight fins. The linear fins 404 are parallel to each other and are parallel to an imaginary center line bisecting the second sub ring 402. The linear fins 404 are substantially aligned along the flow path of the process gases. Alternatively, a plurality of protrusions (not shown) may be disposed on the second sub ring 402 at a segment adjacent the process gas inlet 140 in addition to the linear fins 404 or instead of the linear fins 404. The plurality of protrusions may be the plurality of protrusions 206 shown in FIG. 2C and described in the accompanying text. During operation, process gases flow through the channels between the linear fins 404 or the plurality of protrusions. The linear fins 404 or the protrusions are heated, thus creating more contact area for better preheating of the process gases. The fins 404 may be streamlined for better gas flow dynamic. The dual-ring preheat ring 400 with the second sub ring 402 having a plurality of linear fins 404 or protrusions increases the contact area and the temperature of the second sub ring 402.

In summary, a processing apparatus having a preheat ring is disclosed. The preheat ring may have a plurality of linear fins disposed on a segment of the preheat ring adjacent the process gas inlet for better heating of the process gases since the contact area has increased. The preheat ring may be a dual-ring preheat ring with a second sub ring having a minimum contact to the first sub ring. The minimum contact reduces the heat transferred from the second sub ring to the cold lower liner, thus increases the temperature of the second sub ring.

While the foregoing is directed to embodiments, other and further embodiments may be devised without departing from the basic scope thereof, and the scope thereof is determined by the claims that follow.

1. An apparatus for processing a substrate, comprising:
a chamber body having a side wall and a bottom wall defining an interior processing region;
a substrate support disposed in the interior processing region of the chamber body;
a ring support; and
a preheat ring disposed on the ring support, wherein the preheat ring comprises a plurality of fins disposed adjacent a process gas inlet.

2. The apparatus of claim 1, wherein the ring support is a lower liner coupled to the side wall.

3. The apparatus of claim 1, wherein the plurality of fins comprise silicon carbide or graphite coated with silicon carbide.

4. The apparatus of claim 1, wherein each of the plurality of fins has a first end and a second end that is opposite the first end, and wherein the first and second ends are tapered to a point.

5. The apparatus of claim 1, wherein the plurality of fins occupy a segment that is one third of the preheat ring.

6. The apparatus of claim 1, wherein the plurality of fins are aligned along a flow path of process gases.

7. The apparatus of claim 1, wherein the plurality of fins are parallel to a center line bisecting the preheat ring.

8. An apparatus for processing a substrate, comprising:
a chamber body having a side wall and a bottom wall defining an interior processing region;
a substrate support disposed in the interior processing region of the chamber body;
a ring support;
a first sub ring disposed on the ring support; and
a second sub ring disposed on the first sub ring.

9. The apparatus of claim 8, wherein the ring support is a lower liner coupled to the side wall.

10. The apparatus of claim 8, wherein the second sub ring comprises a slanted stand that contacts the first sub ring.

11. The apparatus of claim 8, wherein the second sub ring further comprises a vertical stand disposed at an end opposite the slanted stand.

12. The apparatus of claim 8, wherein the second sub ring comprises features disposed adjacent a process gas inlet.

13. The apparatus of claim 12, wherein the features occupy a segment that is one third of the second sub ring.

14. The apparatus of claim 12, wherein the features are fins, and the fins comprise silicon carbide or graphite coated with silicon carbide.

15. The apparatus of claim 14, wherein each of the fins has a first end and a second end that is opposite the first end, and wherein the first and second ends are tapered to a point.

16. The apparatus of claim 14, wherein the fins are parallel to a center line bisecting the second sub ring.

17. The apparatus of claim 12, wherein the features are a plurality of protrusions, and the plurality of protrusions include bumps, ridges, or ripples.

18. An apparatus for processing a substrate, comprising:
a chamber body having a side wall and a bottom wall defining an interior processing region;
a substrate support disposed in the interior processing region of the chamber body;
a ring support; and
a preheat ring disposed on the ring support, wherein the preheat ring includes a segment disposed adjacent a process gas inlet, wherein the segment includes a top surface and a plurality of protrusions are disposed on the top surface.

19. The apparatus of claim 18, wherein the plurality of protrusions form radial gas paths.

20. The apparatus of claim 18, wherein the plurality of protrusions form parallel gas paths.
